(19) United States
(12) Patent Application Publication
(10) Pub. No.: US 2007/0046142 A1
(43) Pub. Date: Mar. 1, 2007

(54) Surface acoustic wave device and manufacturing method thereof

(75) Inventors: Ikuo Obara, Kyoto (JP); Shigehiko Nagamine, Kyoto (JP); Kiyohiro Iioka, Kyoto (JP)

Correspondence Address: MORRISON & FOERSTER LLP, 1650 TYSONS BOULEVARD, SUITE 300, MCLEAN, VA, 22102, US

(73) Assignee: KYOCERA Corporation, Kyoto (JP)

(21) Appl. No.: 11/508,326

(22) Filed: Aug. 23, 2006

(30) Foreign Application Priority Data
Aug. 24, 2005 (JP) 2005-243249

(51) Int. Cl. H03H 9/25

(52) U.S. Cl. 310/313 R

(57) ABSTRACT

A surface acoustic wave device includes an excitation electrode formed on a piezoelectric substrate and a binding electrode to be connected with a mounting substrate. The binding electrode is provided with a lower electrode formed on the piezoelectric substrate and an intermediate layer that is made of an adhesion electrode layer and a barrier metal electrode layer. The barrier metal electrode layer includes at least one impurity-containing layer. The binding electrode represents an annular electrode formed to surround the excitation electrode and a wiring electrode connected to the excitation electrode. A surface of at least one of the piezoelectric substrate, the lower electrode and the barrier metal electrode layer is bombarded to make it a rough surface. As a result, a warp due to a film stress caused in each of the layers can be suppressed.

### BACKGROUND OF THE INVENTION

1. Field of the Invention

This invention relates to a surface acoustic wave device and a manufacturing method thereof. The surface acoustic wave device is particularly suitable for use in a wireless communication circuit in mobile communication equipment and the like.

2. Description of the Related Art

The surface acoustic wave devices including a surface acoustic wave resonator, a surface acoustic wave filter and the like are used in a broad range of applications such as various kinds of wireless communication equipment utilizing a microwave band, car-mounted equipment and medical equipment. And the surface acoustic wave devices are required to reduce their sizes as the equipment is made smaller in size.

FIG. 9 is an outline cross-sectional view of a typical surface acoustic wave device 100 according to a prior art.

The surface acoustic wave device 100 includes a surface acoustic wave element S and a mounting substrate 120. The surface acoustic wave element S is provided with a piezoelectric substrate 110, an IDT (Inter Digital Transducer) electrode 111, which is a comb-shaped electrode disposed on the piezoelectric substrate 110, and electrode pads 112, that serve as wiring electrodes for input/output. On the other hand, the mounting substrate 120 is provided with electrode patterns 121 that are connected to external circuits such as a drive circuit, a resonant circuit, a ground circuit and the like. Bump connections 130, which are for connection with the electrode pads 112 and are made of low-melting metallic material such as solder, are formed on the electrode patterns 121.

And in the surface acoustic wave device 100, an annular electrode portion 131, which looks annular on a plan view of the surface acoustic device 100, is formed to keep hermeticity of a space surrounding the IDT electrode 111.

The bump connections 130 are formed by vapor deposition, screen printing, transfer printing, electroless plating, electrolytic plating or the like.

The annular electrode portion 131 is formed by forming a metallization film on the piezoelectric substrate 110 by vapor deposition or the like, followed by patterning the metallization film using photolithography.

The piezoelectric substrate 110 is mounted to the mounting substrate 120 so that each of the electrode pads 112 is aligned with each of the electrode patterns 121 at a corresponding location, respectively. Then the piezoelectric substrate 110 is connected with the mounting substrate 120 electrically as well as mechanically by reflow soldering of the bump connections 130. Also, the piezoelectric substrate 110 is mechanically connected with the mounting substrate 120 through the annular electrode portion 131.

Japanese Patent Application Publication No. H04-293310 discloses that the surface acoustic wave device 100 is mounted using a face down bonding, i.e., a flip chip method, in which a functional surface of the piezoelectric substrate 110, which is provided with the IDT electrode 111 of the surface acoustic element S, is placed to face a surface of the mounting substrate 120, which has the electrode patterns 121, as described above. The contents of this publication are incorporated by reference in their entirety.

FIG. 10 is a cross-sectional view of the electrode pad 112 included in the surface acoustic wave device according to the prior art. As shown in FIG. 9, the surface acoustic wave device is provided with the IDT electrode (the IDT electrode 111 in FIG. 9) made of aluminum or aluminum alloy and the electrode pads 112 to connect the IDT electrode with the external circuits (not shown). The surface acoustic wave device is face down bonded through the bump connections (the bump connections 130 in FIG. 9) formed on the electrode pads 112.

The electrode pad 112 is provided with a lower electrode 113 formed on the piezoelectric substrate 110, a Cr (chrome) layer 114 that is formed on the lower electrode 113 and serves as an adhesive electrode layer, a Ni (nickel) layer 115 formed on the Cr layer 114 and a Au (gold) electrode layer 116 that is made of gold and the like and constitutes a top surface portion of the electrode pad 112.

The lower electrode 113 is formed of aluminum or aluminum alloy. The Cr layer 114 is formed to cover the entire or a part of the lower electrode 113. The Cr layer 114 is interposed between the lower electrode 113 and the Ni layer 115 in order to enhance adhesion strength of the Ni layer 115.

Japanese Patent Application Publication No. H11-234082 discloses that the Ni layer 115 is formed of a single layer of nickel as a barrier metal. The barrier metal means a thin layer of metal interposed between the electrode pad 112 and a layer of other material in order to block phase transformation due to interdiffusion and reaction between two different metal films or between a semiconductor layer and a metal film. The contents of this publication are incorporated by reference in their entirety.

As described in Japanese Patent Application Publication No. H11-234082, the Ni layer 115 included in the electrode pad 112, which serves as the wiring electrode, is formed relatively thick, because the Ni layer 115 is formed to serve as the barrier metal.

The Cr layer 114 and the Ni layer 115, which are interposed between the lower electrode 113 and the Au electrode layer 116, are collectively called an intermediate layer 117 hereinafter.

Since the Ni layer 115 in the intermediate layer 117 is formed relatively thick, a strong film stress may be caused in the Ni layer 115. The film stress caused in the Ni layer 115 is conveyed to all over the electrode pad 112 to reduce bonding strength between the layers as the lower electrode 113, the Cr layer 114 and the Ni layer 115, which constitute the electrode pad 112, can not absorb the film stress at interfaces between them. In particular, since separation is easily caused at the interface between the layers below the Ni layer 115 due to the reduction in the bonding strength between the layers, electric connection to the electrode pad 112 and thus reliability of the surface acoustic wave device 100 can no longer be secured.

The same structure as the electrode pad 112 may be applied to the annular electrode. However, the annular electrode may also have the problem of separation at the interface between the layers constituting the annular electrode due to the film stress caused in the Ni layer 115 included in the intermediate layer 117. Because of it, the annular electrode portion 131 that includes the annular electrode can no longer secure the hermeticity of the space surrounding the IDT electrode 111.

Thus, it is conceived that the surface acoustic wave element S is heated to enhance the adhesive strength of the layers constituting the electrode pad 112 when the electrode pad 112 or the annular electrode is formed so that the separation due to the film stress caused in the Ni layer 115 does not take place.

However, heating the surface acoustic wave element S is not preferable since it may destroy the electrode formed on the piezoelectric substrate 110 through an effect of pyroelectricity that the piezoelectric substrate 110 possesses.

Besides, when the film stress in the Ni layer 115 in the annular electrode portion 131 becomes large, the film stress extends to the piezoelectric substrate 110 to warp the piezoelectric substrate 110 as a result. That causes a lot of problems in the manufacturing process of the surface acoustic wave device such as precise patterning with stepper exposure used in photolithography, carrying the piezoelectric substrate 110 and placing it on a stage by vacuum suction. In addition to the above, the piezoelectric substrate 110 might be broken, especially in vacuum suction, because the warp due to the film stress in the Ni layer 115 is magnified on the piezoelectric substrate 110, when a diameter of the piezoelectric substrate 110 is large.

In the manufacturing process to form the electrode pad 112 in which the lower electrode 113 and then the intermediate layer 117 are formed using a lift-off method, a photoresist film 119 which is tapered down to the bottom to have overhung shape is first formed in regions other than a region where the intermediate layer 117 and the Au electrode layer 116 are to be formed, as shown in FIG. 11. Then the Cr layer 114, the Ni layer 115 and the Au electrode layer 116 are stacked to form the electrode pad 112 while the photoresist layer 119 provides masking.

As each of the layers 114, 115 and 116 that form the electrode pad 112 is stacked on the lower electrode 113, each of the corresponding layers 134, 135 and 136 is stacked on the photoresist layer 119 at the same time. As a result, the film stress caused in the Ni layer 135 formed on the photoresist film 119 extends to the photoresist film 119. That causes a warp in the photoresist film 119, thus the photoresist film 119 is lifted at edges adjacent its opening, making the opening larger than a designed area. As a result, the materials forming the intermediate layer 117 are deposited beyond the designed area of the lower electrode 113, forming burrs around the lower electrode 113 made of aluminum or aluminum alloy. When the burrs are deposited in a larger area than the designed area, they may be short-circuited to the IDT electrode 111.

In addition, since the burrs are deposited very thin, the burrs adhere to the substrate or the electrode weakly and are easy to come off. When the burrs come off, they are prone to short-circuit to a neighboring electrode to cause a failure in characteristics of the surface acoustic wave device.

Thus, the Ni layer 115 (135) may be reduced in thickness to reduce the film stress caused in the Ni layer 115 (135) as described above.

When the Ni layer 115 (135) is made extremely thin, however, the Ni layer 115 does not function as the barrier metal as originally intended.

Considering the situation described above, this invention provides a surface acoustic wave device having a binding electrode that includes an electrode layer sufficiently functioning as a barrier metal against a low-melting metallic material such as solder, while a film stress caused in the electrode is relaxed to attain high hermeticity and high reliability. The invention also provides a method of manufacturing the surface acoustic wave device.

### SUMMARY OF THE INVENTION

The invention provides a surface acoustic wave device that includes a piezoelectric substrate having a first electrode formed on the primary surface of the piezoelectric substrate to generate a surface acoustic wave, a mounting substrate, and a second electrode attaching the piezoelectric substrate to the mounting substrate. The second electrode includes a lower electrode made of an aluminum-based metal and formed on the primary surface of the piezoelectric substrate, an adhesion layer formed on the lower electrode and a barrier metal layer formed on the adhesion layer. The barrier metal layer includes a first metal layer and a second metal layer that has more impurities than the first metal layer.

The invention also provides a method of manufacturing a surface acoustic wave device. The method includes providing a piezoelectric substrate having an electrode formed on the primary surface of the piezoelectric substrate to generate a surface acoustic wave, forming a lower electrode made of an aluminum-based metal on the primary surface of the piezoelectric substrate, forming an adhesion layer on the lower electrode, forming a barrier metal layer on the adhesion layer so that the barrier metal layer includes a first metal layer and a second metal layer that has more impurities than the first metal layer, and attaching a mounting substrate to the piezoelectric substrate using a stack of the lower electrode, the adhesion layer and the barrier metal layer.

### BRIEF DESCRIPTIONS OF THE DRAWINGS

FIG. 1 is a plan view showing a surface acoustic wave device, according to an embodiment of this invention.

FIG. 2 is a magnified cross-sectional view of a section A-A′ of an annular electrode shown in FIG. 1.

FIG. 3 is a magnified cross-sectional view of a section B-B′ of a wiring electrode shown in FIG. 1.

FIG. 4 is a cross-sectional view of the surface acoustic wave device in which a surface acoustic wave element is mounted on a mounting substrate.

FIG. 5 is a magnified cross-sectional view to explain a manufacturing method of a binding electrode.

FIG. 6 is a magnified cross-sectional view showing the binding electrode formed by a lift-off method.

FIG. 7 shows results of SIMS (Secondary Ion Mass Spectrometry) analysis showing metal and other elements constituting each of layers disposed at various depths from a surface of the bonding electrode.

FIG. 8 shows results of SIMS (Secondary Ion Mass Spectrometry) analysis showing metal and other elements constituting each of layers disposed at various depths from a surface of a bonding electrode (electrode pad), according to a prior art.

FIG. 9 is an outline cross-sectional view of a typical surface acoustic wave device, according to the prior art.

FIG. 10 is a cross-sectional view of the electrode pad included in the surface acoustic wave device, according to the prior art.

FIG. 11 is a cross-sectional view showing the electrode pad formed by the lift-off method, according to the prior art.

FIG. 12 is a block circuit diagram of a high frequency circuit having a band-pass filter, according to the embodiment of this invention.

FIG. 13 is a magnified cross-sectional view of a section A-A′ of an annular electrode shown in FIG. 1, according to a modification of the embodiment of this invention.

### DETAILED DESCRIPTION OF THE INVENTION

An embodiment of this invention is hereinafter described in detail, referring to the drawings.

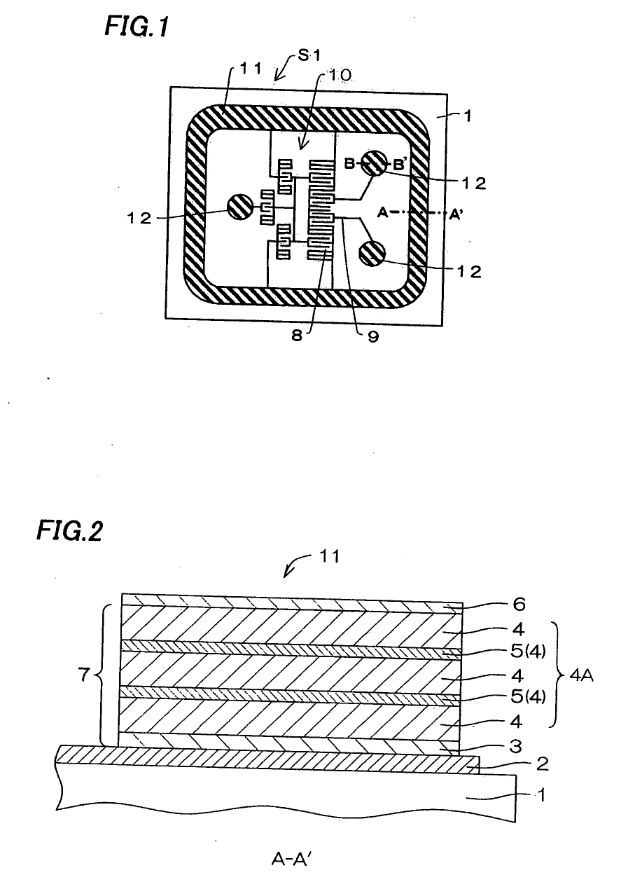

FIG. 1 is a plan view showing a surface acoustic wave device, according to the embodiment of this invention. A surface acoustic wave element S1 is provided with a piezoelectric substrate 1, IDT electrodes 8 having comb-shaped electrodes, wiring electrodes 12 for input/output electric signals to/from the IDT electrodes 8, extension wirings 9 to connect between the IDT electrodes 8 and the wiring electrodes 12 and an annular electrode 11 to hermetically seal a space surrounding the IDT electrodes 8. And a protection film 10 is formed on the IDT electrodes 8 and the extension wirings 9 on a surface (a primary surface) of the piezoelectric substrate 1, on which the IDT electrodes 8 are formed.

The piezoelectric substrate 1 is formed using a piezoelectric material such as 36° rotated Y-cut X-propagation single crystalline LiTaO₃, 64° rotated Y-cut X-propagation single crystalline LiNbO₃ or 45° rotated X-cut Z-propagation single crystalline LiB₄O₇, for example. As a result, the piezoelectric substrate 1 can be made to have a large electromechanical coupling factor and a small group delay time temperature coefficient.

And a thickness of the piezoelectric substrate 1 is preferably about 0.3-0.5 mm. With that thickness, the piezoelectric substrate 1 is not as fragile as it is when formed less than 0.3 mm thick, and not as expensive in material cost as it is when formed thicker than 0.5 mm.

The IDT electrodes 8 are excitation electrodes to generate a surface acoustic wave. The IDT electrodes 8 include pairs of comb-shaped electrodes interdigitating with each other. The IDT electrodes 8 preferably have 50-200 pairs of electrodes, 0.1-10 μm of electrode finger width, 0.1-10 μm of electrode finger spacing and 10-80 μm of interdigitating width of the electrode fingers. And the IDT electrodes 8 have 0.2-0.4 μm of thickness in order to obtain intended characteristics as a surface acoustic wave resonator or a surface acoustic wave filter. The IDT electrodes 8 may have a structure provided with reflectors at both ends of a propagation path of the surface acoustic wave, so that the generated surface acoustic wave is reflected to resonate effectively.

And the IDT electrodes 8 are made of metallic material that is Al—Cu base aluminum alloy. Metals added to the Al—Cu base aluminum alloy other than Cu may include Ti, Ta, W, Mo or the like. The IDT electrodes 8 may be formed of stacked layers of aluminum alloy that include Ti, Ta, W, Mo or the like.

And the IDT electrodes 8 may be applied to a slit type reflector in which a plurality of electrode fingers is arrayed in parallel. The IDT electrodes 8 are not limited to form a surface acoustic wave filter which is a mixture of a double mode surface acoustic wave resonator filter and a ladder type surface acoustic wave filter as shown in FIG. 1, and may form the double mode surface acoustic wave resonator filter or the ladder type surface acoustic filter.

The IDT electrodes 8 are connected with a plurality of wiring electrodes 12 through a plurality of extension wirings 9. The IDT electrodes 8 and the extension wirings 9 are covered with an insulative protection film 10.

The wiring electrodes 12 are made of conductive metallic material. The IDT electrodes 8 in the surface acoustic wave element S1 are electrically and mechanically connected with external wirings (not shown) connected to a mounting substrate (not shown) by bonding the wiring electrodes 12 to wiring connection electrodes (not shown) on the mounting substrate formed at locations facing to the wiring electrodes 12 through the low-melting metallic material such as solder.

The annular electrode 11 is formed to surround the IDT electrodes 8. And the surface acoustic wave element S1 is mechanically connected with the mounting substrate by bonding the annular electrode 11 to annular connection electrode (not shown) on the mounting substrate formed at a location facing the annular electrode 11 through the low-melting metallic material such as solder.

The IDT electrodes 8 and the extension wirings 9 are formed of aluminum alloy that is predominantly composed of aluminum by thin film forming method such as sputtering, vapor deposition or CVD (Chemical Vapor deposition). Predetermined shapes are formed by patterning using photolithography.

The protection film 10 is formed of insulator such as a SiO₂ film, a SiN film or a Si film by thin film forming method such as CVD or vapor deposition.

The surface acoustic wave element S1 is provided with at least a pair of IDT electrodes 8 as described above. The surface acoustic wave element S may be provided with multiple pairs of IDT electrodes connected in series or parallel, in order to obtain desired characteristics.

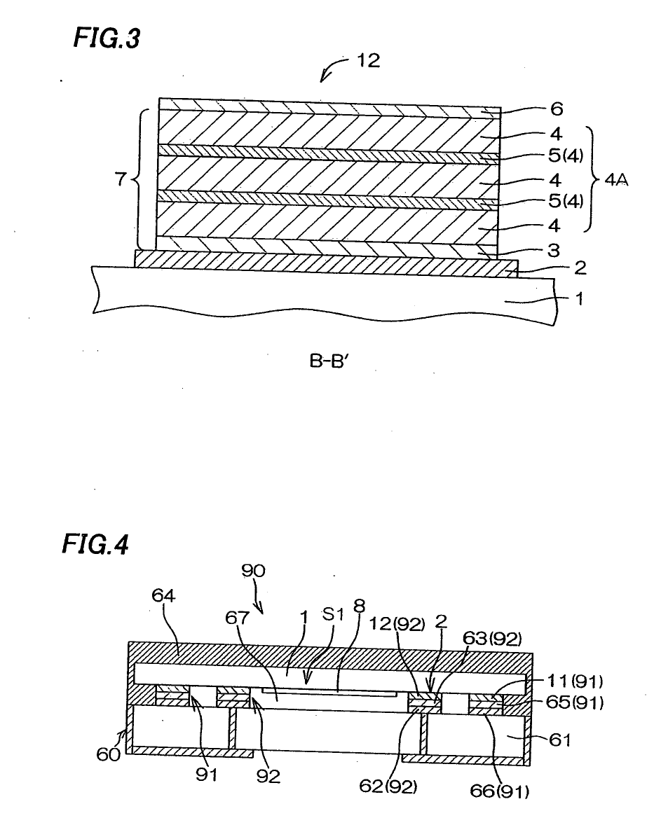

FIG. 2 is a magnified cross-sectional view of a section A-A′ of the annular electrode 11 shown in FIG. 1. FIG. 3 is a magnified cross-sectional view of a section B-B′ of the wiring electrode 12 shown in FIG. 1.

The annular electrode 11 includes a lower electrode 2 made of aluminum alloy, an adhesion electrode layer 3 formed on the lower electrode 2, a barrier metal electrode layer 4 formed on the adhesion electrode layer 3 and an Au electrode layer 6 that makes a top layer of the annular electrode 11. In this embodiment, the barrier metal electrode layer 4 is made of a stack of five layers. The stack is made of three base material layers 4A, which are made of base material of the barrier metal electrode layer 4 only, and two impurity-containing layers 4B, each interposed between the base material layers 4A. In this embodiment, the impurity-containing layers 4B are made by adding impurities to the base material of the barrier metal electrode layer 4. The adhesion layer 3 and the barrier metal electrode layers 4, which are interposed between the lower electrode 2 and the Au electrode layer 6, are collectively called an intermediate layer 7 hereinafter.

The lower electrode 2 is formed of aluminum alloy, principal component of which is aluminum, using a thin film forming method such as sputtering, vapor deposition or CVD. The lower electrode 2 is 0.2-0.4 μm thick. A predetermined shape is formed by patterning using photolithography.

The adhesion electrode layer 3 is formed using a material including Cr, Ti, V, Pt or the like in order to enhance adhesiveness to the lower electrode 2. When the adhesion electrode layer 3 is formed using Cr or Ti from among the materials mentioned above, the adhesiveness to the lower electrode 2 made of aluminum alloy can be particularly enhanced. The adhesion electrode layer 3 is 0.01-0.03 μm thick.

A material including Ni or Cu is used to form the barrier metal electrode layer 4 in order to suppress diffusion of solder. Because the diffusion of solder can be suppressed as a result, formation of a fragile intermetallic compound and separation between the metal layers can be suppressed to enhance reliability of the surface acoustic wave device. Especially when the barrier metal electrode layer 4 is formed using Ni from among the materials mentioned above, diffusion velocity of solder can be made slower compared with the case when Cu is used. Thus the diffusion of solder reaching down to the lower electrode 2 during reflow soldering can be suppressed more effectively.

To form the impurity-containing layers 4B stacked in the barrier metal electrode layer 4, Ni is used as a principal material and impurity such as carbon, sulfur or oxygen is added in order to reduce the film stress caused in the barrier metal electrode layer 4. When carbon or oxygen is used as the impurity added to the impurity-containing layer 4B, the film stress caused in the intermediate layer 7 can be especially reduced. In particular, when carbon is used as the impurity, the impurity-containing layer 4B can improve insertion loss of the surface acoustic wave element S1 because electric resistance of the annular electrode 111 including the impurity-containing layer 4B is reduced.

In this embodiment, the impurity concentration of carbon was 3.0 to 3.5% by weight. Sulfur and oxygen are expected to have similar impurity concentrations or lower impurity concentrations than the impurity concentration of carbon. It is noted that the intrinsic impurity concentration for carbon, sulfur or oxygen prior to intentional impurity doping is a few ppm.

It is preferable that a film thickness of the overall barrier metal electrode 4 (denoted as 4 in FIG. 2) including the impurity-containing layers 4B is in a range from 0.5 μm to 1.5 μm. With that thickness, the barrier metal electrode layer 4 is not insufficient in functioning as the barrier metal as it is when thinner than 0.5 μm, and does not cause significantly large film stress as it does when thicker than 1.5 μm.

The barrier metal electrode layer 4 including the impurity-containing layer 4B is not necessarily structured to have clear boundaries between the layers as shown in FIG. 2, and may be structured that the impurity concentration gradually varies along a direction of thickness of the barrier metal electrode layer 4. In other words, it may be structured to have an impurity concentration gradient in the direction of thickness of the barrier metal electrode layer 4. Such structure can be formed by gradually changing an impurity concentration in an ambient atmosphere in a film forming apparatus when the barrier metal electrode layer 4 is formed by thin film forming method such as sputtering, vapor deposition or the like, or by using a target having an impurity concentration gradient when the barrier metal electrode layer 4 is formed by sputtering.

The adhesion electrode layer 3, the barrier metal electrode layer 4 and the Au electrode layer 6 are formed one after another by thin film forming method such as sputtering or vapor deposition to form the annular electrode 11. And the lift-off method is used to obtain the predetermined shape of the annular electrode 11. The process to form the annular electrode 11 (binding electrode) using the lift-off method will be described later.

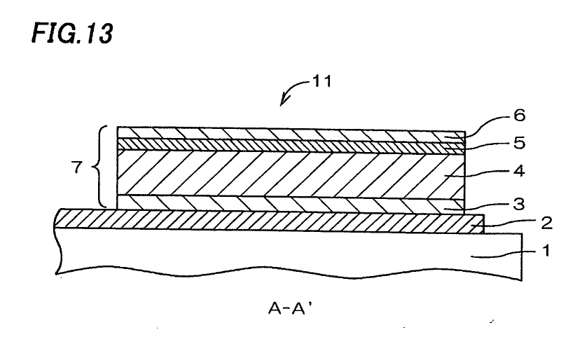

The film stress caused in the intermediate layer 7 can be sufficiently reduced even when there is only one pair of the base material layer 4A and the impurity-containing layer 4B between the adhesion electrode 3 and the Au electrode layer 6, as shown in FIG. 13.

In sum, the stacking structures 4 shown in FIGS. 3 and 13 are configured to attach the mounting substrate and the piezoelectric substrate, to provide the electrode with electric connection and to reduce the residual stress between the piezoelectric substrate and the mounting substrate preferably below 200 N/m². However, depending on the device design, the stacking structure may accommodate higher film stresses.

The wiring electrode 12 may be formed by stacking the intermediate layer 7 and the Au electrode layer 6 on the lower electrode 2 one after another in the same way as the annular electrode 11 is formed, as shown in FIG. 3. Therefore, the wiring electrode 12 and the annular electrode 11 can be formed in the same process steps.

FIG. 4 is a cross-sectional view of a surface acoustic wave device 90 in which the surface acoustic wave element S1 is mounted on a mounting substrate 60.

The mounting substrate 60 included in the surface acoustic wave device 90 is provided with a base 61, an annular connection electrode 66 and wiring connection electrodes 62. And an annular sealing material 65, which is to be directly bonded to the annular electrode 11, is formed on the annular connection electrode 66. Connection bodies 63 that are to be bonded to the wiring electrodes 12 are formed on the wiring connection electrodes 62. A structure in which the annular electrode 11 is directly bonded to the electrode (annular connection electrode 66) as the binding electrode means a structure in which the annular electrode 11 is connected with the annular connection electrode 66 through the connection material (annular sealing material 65) such as solder or a conductor bump, that is, a structure such as a flip chip connection in which wires such as bonding wires are not used.

The base 61 may be made of stacked layers of a ceramic substrate and a frame-shaped ceramic substrate. Or it may be made of a single ceramic substrate only.

The wiring connection electrodes 62 and the annular connection electrode 66 are formed on the base 61 by electrolytic plating, electroless plating or the like.

Although it is described above that the connection bodies 63 are formed on the wiring connection electrodes 62, they may be formed on the wiring electrodes 12.

The annular sealing material 65 formed on the annular connection electrode 66 and the connection bodies 63 formed on the wiring connection electrodes 62 are formed by applying metallic material such as solder paste or Au—Sn paste using printing method such as screen printing. It is also possible to form the annular sealing material 65 and the connection bodies 63 simultaneously by applying the metallic material using a dispenser method.

Although it is described above that the annular connection material 65 is formed on the annular connection electrode 66, it may be formed on the annular electrode 11.

The connection bodies 63 formed on the wiring connection electrodes 62 may be formed by applying and patterning an anisotropic conductive resin, that is an epoxy resin mixed with conductive filler such as silver filler, using a printing method or a dispenser method, for example. Viscosity of the epoxy resin composing the connection bodies 63 may be adjusted by adding thixotropic additive or by controlling an amount of the filler so that the resin does not spread broader than required. The connection bodies 63 are preferably as low in impurity ion concentration as possible in order to prevent electrode corrosion of the surface acoustic wave element S1. The connection bodies 63 may be formed by applying and patterning the anisotropic conductive resin using photolithography.

The surface acoustic wave device 90 is manufactured by following process steps.

First, the surface acoustic wave element S1 is mounted and fixed to the mounting substrate 60 face-down, so that the primary surface on which the IDT electrodes 8 are formed faces to a top surface of the base 61.

The wiring electrodes 12 are connected with the wiring connection electrodes 62, which are formed at the locations facing to the wiring electrodes 12, through the connection bodies 63. And the annular electrode 11 is connected with the annular connection electrode 66, which is formed at the location facing to the annular electrode 11, through the annular sealing material 65. Then the surface acoustic wave element S1 is placed in a reflow furnace together with the mounting substrate 60 to which the surface acoustic wave element S1 is mounted. The connection bodies 63 and the annular sealing material 65 are reflow-melted, and then taken out of the reflow furnace and cooled down to room temperature to be cured. The wiring electrodes 12, the wiring connection electrodes 62 and the connection bodies 63 form wiring electrode portions 92, while the annular electrode 11, the annular connection electrode 66 and the annular sealing material 65 form an annular electrode portion 91. With them, the surface acoustic wave element S1 is electrically and mechanically connected with the mounting substrate 60.

The annular electrode portion 91, together with the primary surface of the surface acoustic wave element S1 and a mounting surface of the mounting substrate 60, forms a vibration space 67 around the IDT electrodes 8. The vibration space 67 is hermetically sealed. Preferably the vibration space 67 is filled with low humidity air and hermetically sealed in order to suppress deterioration due to oxidation of the IDT electrodes 8 or the like. Or it may be filled with inert gas such as nitrogen gas or argon gas instead of the air described above, in order to further suppress the deterioration due to the oxidation or the like.

After that, a resin 64 is applied to another primary surface and surrounding surface of the surface acoustic wave element S1 by potting or printing, and then the resin 64 is hot cured by heating. Dicing along separation lines between the surface acoustic wave elements S1 completes the surface acoustic wave device 90.

The surface acoustic wave device 90 has good hermeticity, high moisture resistance and thus excellent reliability because the vibration space 67 is surrounded by the annular electrode portion 91 and the resin 64.

And the film stress caused in the barrier metal electrode layer 4 can be relaxed because there is at least one impurity-containing layer 4B in the barrier metal electrode layer 4 which is used as the intermediate layer 7 of the annular electrode 11. As a result, the separation of the electrode due to the film stress in the annular electrode 11 is not likely to occur, and the hermeticity of the vibration space 67 is sufficiently secured.

In addition, because the film stress is not likely to occur in each of the layers forming the annular electrode portion 91 and thus the warp is not likely to occur in the surface acoustic wave device 90, the vibration space 67 can be manufactured precisely to designed dimensions. This allows more sophisticated design, enhancing reliability while reducing a thickness and a size of the surface acoustic wave device 90.

A manufacturing method of the annular electrode 11 and the wiring electrode 12 will be described below. The annular electrode 11 and the wiring electrode 12 are collectively called a binding electrode E hereinafter.

FIG. 5 is a magnified cross-sectional view to explain the manufacturing method of the binding electrode E. Interfaces between the layers constituting the binding electrode E are made rough in the embodiment. As a result, the film stress caused in each of the layers can be further absorbed. Here, the manufacturing method of the binding electrode E is described including process steps to make the surfaces of the layers rough.

The binding electrode E (the annular electrode 11 or the wiring electrode 12) includes the lower electrode 2 made of Al alloy, the intermediate layer 7 that includes the adhesion electrode layer 3 and the barrier metal electrode layer 4 formed on the lower electrode 2, and the Au electrode layer 6 forming a top layer of the wiring electrode 12. And in the barrier metal electrode layer 4, there is at least one impurity-containing layer 4B interposed between the base material layers 4A. There are two impurity-containing layers 4B in the embodiment.

First, the lower electrode 2 is formed on the piezoelectric substrate 1 by depositing a film of metallic material such as aluminum-based alloy using a thin film forming method such as sputtering, vapor deposition or CVD. A predetermined shape is formed by patterning the film using photolithography.

Next, the adhesion electrode 3 and the barrier metal electrode layer 4, together making the intermediate layer 7, and the Au electrode layer 6 at the top of them are formed one after another in the order mentioned above by a thin film forming method such as sputtering or vapor deposition.

By switching to a Ni target having high concentration of carbon or sulfur during the sputtering to form the barrier metal electrode layer 4, the impurity-containing layer 4B that has high concentration of carbon or sulfur is formed in the barrier metal electrode layer 4 grown at the time. The impurity concentration in the target material is preferably 3.0 to 3.5% by weight.

As an alternative method to form the barrier metal electrode layer 4 including the impurity-containing layer 4B, a method to mix an inert gas such as argon used as a sputtering gas with a doping gas including carbon or sulfur may be used.

Or the impurity-containing layer 4B may be formed by providing a halt period (interval) of sputtering while the barrier metal electrode layer 4 is formed by the sputtering. That is, after a first layer constituting the barrier metal electrode layers 4 is formed, the sputtering is temporarily halted, and then restarted. By doing so, the first layer constituting the barrier metal electrode layer 4 makes a first base material layer 4A that includes approximately the same low impurity concentration as that in the target, because it is formed to include the impurities included in the target intact. In a second layer constituting the barrier metal electrode layer 4 that is formed after restarting the sputtering, on the other hand, the impurity-containing layer 4B of high impurity concentration, that is about the sum of the impurity concentration in the target and impurity concentration in an ambient atmosphere, is formed first because the impurity in the ambient atmosphere is incorporated into the impurity-containing layer 4B at the restart of the sputtering, and then a second base material layer 4A that includes approximately the same low impurity concentration as that in the target is formed next. As a result, the impurity-containing layer 4B is formed between the first base material layer 4A and the second base material layer 4A. An impurity gradient is easily formed when the impurity-containing layer 4B is formed by the sputtering with the interval as described above.

Although a functional mechanism of the incorporation of the impurities in the ambient atmosphere at the restart of the sputtering is not clear, an experiment conducted by the inventors has confirmed that the impurity-containing layer 4B is formed at the restart of the sputtering.

When the layers in the binding electrode E are formed, a surface of at least one of the layers is cleaned by bombarding its surface with at least one of argon ions, oxygen ions and nitrogen ions prior to its formation. The surface of the bombarded layer in the binding electrode E is made rough by the bombardment (The surfaces of all the layers shown in FIG. 5 are bombarded). The warp due to the film stress caused in each of the layers can be further suppressed especially by making the interface of the layers forming the binding electrode E rough.

A manufacturing process of the binding electrode E on the surface acoustic wave element S1 by the lift-off method will be described hereinafter.

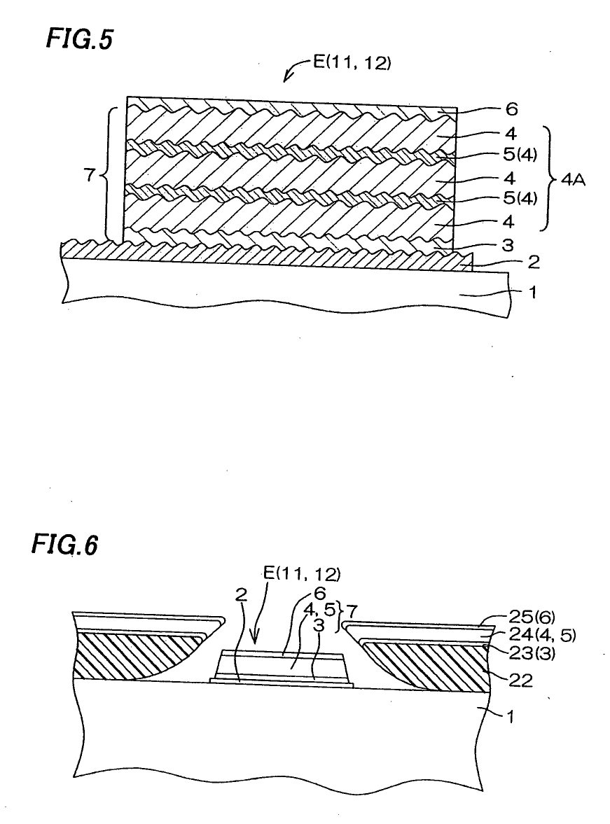

FIG. 6 is a magnified cross-sectional view showing the binding electrode E formed by the lift-off method. In the binding electrode E, there are the intermediate layer 7 and the Au electrode layer 6 formed one after another on the lower electrode 2, as described above.

First, a photoresist film 22 which is tapered down to the bottom to have overhung shape is formed on the piezoelectric substrate 1 in regions other than a region where the intermediate layer 7 is to be formed. Next, the binding electrode E is formed by stacking the adhesion electrode layer 3, the barrier metal electrode layer 4 and the Au electrode layer 6 one after another, while masking is provided by the photoresist film 22. A Cr layer 23, a Ni layer 24 and an Au layer 25 are stacked on the photoresist film 22 at the same time as the binding electrode E is formed. The Ni layer 24 has the impurity-containing layers in it as the barrier metal electrode layer 4. Because of that, the film stress in the Ni layer 24 is reduced to make it not likely that the photoresist film 22 is lifted at edges adjacent to its opening in the lift-off process to form the binding electrode E. Therefore, burrs caused in the formation of the binding electrode E are reduce, and the adhesion electrode 3, the barrier metal electrode layer 4 and the Au electrode layer 6 can be formed nearly precisely positioned as designed. Thus the manufacturing method of the binding electrode E described above can reduce short-circuit failures due to the burrs and improve a yield as a result.

Although the binding electrode E is formed using the lift-off method in the manufacturing process described above, it may be formed using a thin film forming method that uses a metal mask such as a photolithography.

The surface acoustic wave device of this embodiment can be applied to a band-pass filter in a communication apparatus such as a mobile telephone and a PHS (Personal Handy Phone) and a communication apparatus. In this case, the band-pass filter means a band-pass filter used in a transmission circuit in the communication apparatus equipped with the transmission circuit outputting an antenna transmission signal to an antenna through a duplexer, and includes the surface acoustic wave device of this embodiment. And the surface acoustic wave device of this embodiment can be also applied to a band-pass filter used in a receiving circuit in a communication apparatus equipped with the receiving circuit that receives an antenna received signal through a duplexer and separates a received signal from a carrier wave signal in the antenna received signal.

And the communication apparatus is provided with a transmission circuit including a mixer that superimposes a transmission signal on a carrier wave signal (carrier signal) to generate an antenna transmission signal, a band-pass filter that includes the surface acoustic wave device of this embodiment and attenuates an unnecessary signal in the antenna transmission signal, and a power amplifier that amplifies the antenna transmission signal and outputs the amplified antenna transmission signal to an antenna through a duplexer. The communication apparatus is also provided with a receive circuit including a low noise amplifier that amplifies an antenna received signal that has been received by the antenna and has gone through a duplexer, a band-pass filter that includes the surface acoustic wave device of this embodiment and attenuates an unnecessary signal in the amplified antenna received signal, and a mixer that separates a received signal from a carrier wave signal in the antenna received signal.

The communication apparatus may be provided with one or both of the transmission circuit and the receive circuit described above.

The band-pass filter and the communication apparatus have excellent durability and high reliability since they include the surface acoustic wave device of this embodiment.

FIG. 12 shows an example of a block circuit diagram of a high frequency circuit having a band-pass filter and incorporated in a mobile phone, that serves as a communication apparatus. A transmission signal (high frequency signal) is superimposed on a carrier wave signal to make an antenna transmission signal by a mixer 220. An unnecessary signal in the antenna transmission signal is attenuated by a surface acoustic wave device 221 that serves as a band-pass filter. After amplified by a power amplifier 222, the antenna transmission signal goes through an isolator 223 and a surface acoustic wave branching filter (duplexer) 215 and radiates from an antenna 214. And an antenna received signal received by the antenna 214 goes through the surface acoustic wave branching filter 215 and is amplified by a low noise amplifier 216. After its unnecessary signal is attenuated by a surface acoustic wave device 217 that serves as a band-pass filter, the amplified antenna received signal is amplified again by an amplifier 218 and is transformed into a low frequency signal by a mixer 219.

### EXAMPLES

Results of manufacturing of and measurements on the surface acoustic wave device 90 manufactured according to the embodiment will be described hereinafter.

36° rotated Y-cut X-propagation crystalline LiTaO₃ was used as the piezoelectric substrate 1. A size of the piezoelectric substrate was 1.1 mm×1.5 mm. An alumina substrate of a size of 70 mm×70 mm and of a thickness of 250 μm was used as the mounting substrate 60. Au and Ni of a total thickness of 1 μm were formed on the alumina substrate using electroless plating.

Regions other than regions where the lower electrode 2 extended from the IDT electrodes 8 and the annular electrode 11 were to be formed were covered with the photoresist film 22 in order to use the lift-off method, as shown in FIG. 6. Then, the binding electrode E (the wiring electrode 12 and the annular electrode 11) was formed using sputtering.

In forming the binding electrode E, the lower electrode 2 was formed of Al—Cu alloy, the adhesion electrode layer 3 was formed of Cr, the barrier metal electrode layer 4 was formed of Ni and the top electrode layer 6 was formed of Au.

Thicknesses of the electrode layers constituting the binding electrode E were 180 nm for the lower electrode 2, 20 nm for the adhesion electrode layer 3, 1 μm for the barrier metal electrode layer 4 including the impurity-containing layers 4B, and 200 nm for the top electrode layer 6.

Forming in the barrier metal electrode layer 4 two impurity-containing layers 4B, that contain high concentration of carbon and sulfur, was made possible by switching to the Ni target material with high concentration of carbon and sulfur during film forming by sputtering (FIG. 2).

Solder paste that was to make the connection bodies 63 and the annular sealing material 65 were applied in advance over the wiring connection electrodes 62 and the annular connection electrode 66 on the mounting substrate 60 using screen printing. A line width of the applied solder paste was about 100 μm.

The surface acoustic wave element S1 was placed face down on the mounting substrate 60, so that each of the wiring electrodes 12 was aligned to face corresponding each of the wiring connection electrodes 62, and kept at 240° C. for 5 minutes in a reflow furnace and then left at room temperature for the molten solder to solidify.

Next, the epoxy resin 64 was applied on top of the surface acoustic wave element S1 by potting, and was cured at 150° C. for 5 minutes in a drying furnace.

Finally, the surface acoustic wave device 90 of a size of 2.5 mm×2.0 mm was completed by dicing along separation lines between chips. The surface acoustic wave device 90 was about 0.7 mm thick.

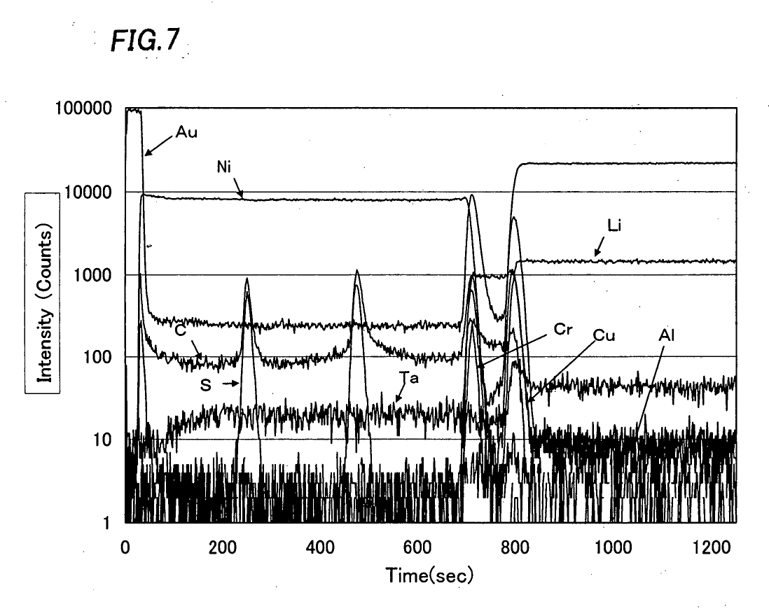

FIG. 7 shows results of SIMS (Secondary Ion Mass Spectrometry) analysis showing distributions of metal and other elements composing the layers as a function of depth from the surface of the binding electrode E.

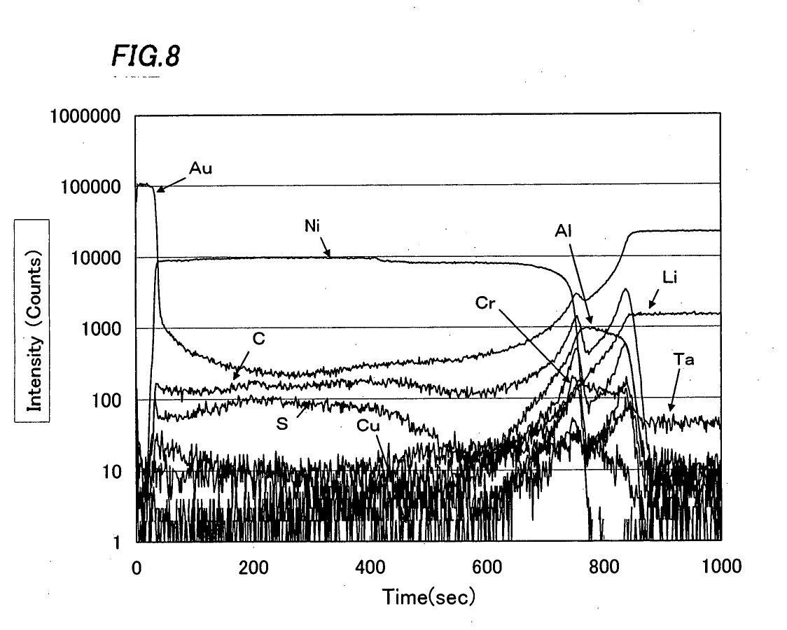

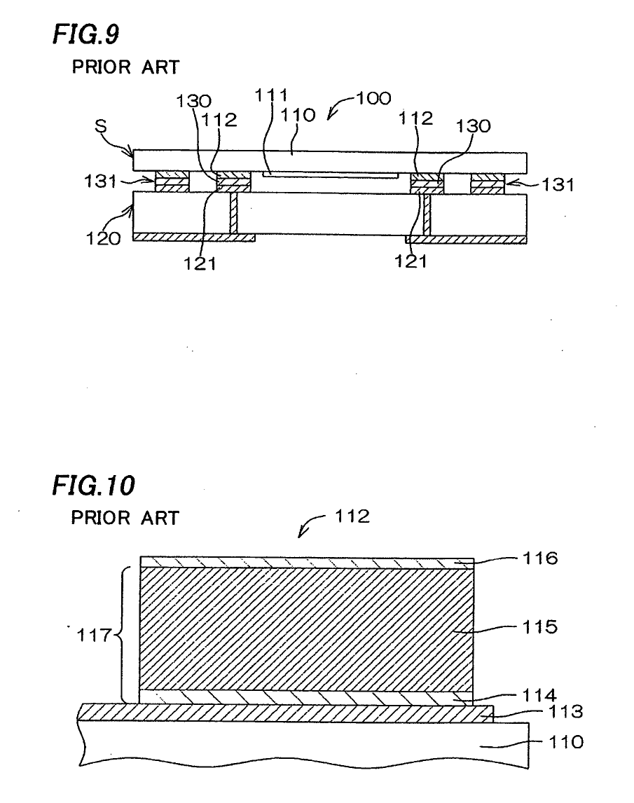

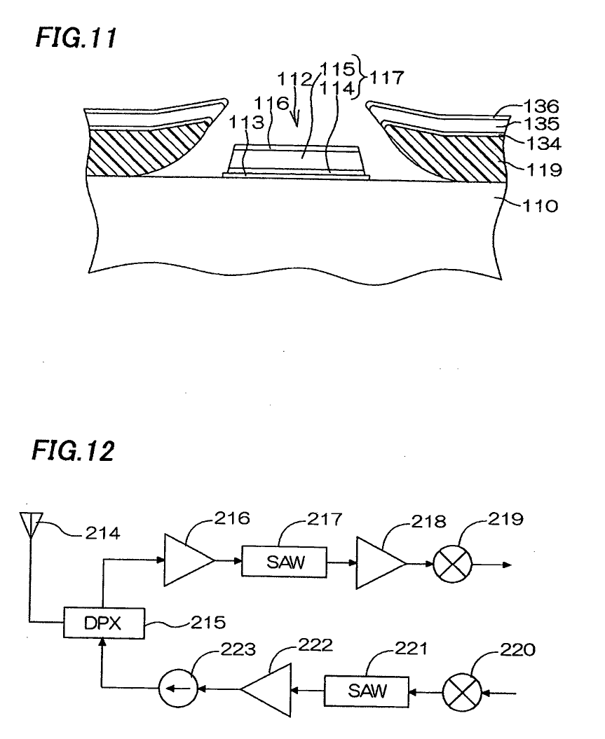

FIG. 8 shows results of the SIMS analysis showing distributions of metal and other elements composing the layers as a function of depth from the surface of the bonding electrode (electrode pad) 112 according to the prior art (FIG. 9).

SIMS is a method of analyzing a sample in which an accelerated and highly focused beam of primary ions (oxygen or cesium ions) bombards a surface of the sample in vacuum and secondary ions out of particles sputtered from the surface are extracted by an electric field and analyzed in a mass spectrometer. Absolute concentrations are calculated by comparison between the sample and a correlation standard.

Regarding the intermediate layer 7 according to the embodiment (FIG. 2), FIG. 7 shows that there are peaks of impurity concentrations of carbon (C) and sulfur (S) (around 200-300 sec. and around 400-500 sec.) in the Ni layers in the barrier metal electrode layer 4. It shows that the barrier metal electrode layer 4 is a stack of layers including two impurity-containing layers 4B each interposed between the Ni layers. The carbon impurity concentrations in the impurity-containing layers 4B was 3.16% by weight. The sulfur impurity concentrations in the impurity-containing layers 4B was 0.5% by weight.

Regarding the intermediate layer 117 according to the prior art (FIG. 10), on the other hand, FIG. 8 shows that the barrier metal electrode layer 115 is made of a single Ni layer.

The film stress in the binding electrode E according to the embodiment is compared with the film stress in the bonding electrode (electrode pad) 112 according to the prior art hereinafter.

Table 1 shows results of measurements on the film stresses in the intermediate layer 7 in the binding electrode E and the intermediate layer 117 in the bonding electrode (electrode pad) 112.

TABLE 1

| Structure of | Embodiment | Prior Art |
|---|---|---|
| Intermediate | (including two Impurity- | (not including Impurity- |
| Layer | containing layers 4B) | containing Layer) |
| Film Stress (N/m²) | 189 ± 17 | 882 ± 79 |

Table 1 compares the binding electrode E (Refer to FIG. 2.) having the impurity-containing layer 4B, that includes carbon and sulfur as impurities, in the barrier metal layer 4 in the intermediate layer 7 according to the embodiment with the bonding electrode 112 that does not include the impurity-containing layer in the Ni layer 115 in the intermediate layer 117 according to the prior art as shown in FIG. 10.

The film stress in the binding electrode E was 189 N/m². On the other hand, the film stress in the bonding electrode 112 was 882 N/m². As a result of using the binding electrode E according to the embodiment, the film stress was reduced to ¼. Therefore, the binding electrode E could prevent separation of the film at the interface of the electrode layers due to the film stress and improve reliability of the surface acoustic wave device.

In addition, mechanical strength was evaluated by free-fall drop tests using the same samples of the surface acoustic wave device 90 and the reference samples according to the prior art as prepared for the measurements of the film stresses described above. The samples were let free-fall from a height of 1.8 m to a surface of a concrete floor. The numbers of the free-fall drop test cycles were 10, 30, 50 and 100. 30 each of the surface acoustic wave devices 90 and the reference samples were prepared for each set of the tests. A sample deteriorated in filter characteristics was regarded as a failure. Cumulative failures were counted for each set of the tests. Results are shown in Table 2.

TABLE 2
n = 30 each

Number of Free-Fall
Drop Test Cycles

| | 10 | 30 | 50 | 100 |
|---|---|---|---|---|
| Embodiment | 0 | 0 | 0 | 0 |
| Reference | 0 | 1 | 3 | 5 |

*Number of Cumulative Failures

There was found not a single failure in the surface acoustic wave device 90 even after 100 cycles of free-fall drop tests. On the other hand, a failure was found in the reference samples according to the prior art after 30 cycles of free-fall drop tests. The data supplement the results of the film stress measurements described above, and show superiority of the surface acoustic wave device 90 over the prior art more practically.

What is claimed is:

1. A device comprising:
a piezoelectric substrate,
a first electrode formed on a primary surface of the piezoelectric substrate to generate a surface acoustic wave,
a mounting substrate, and
a second electrode attaching the piezoelectric substrate and the mounting substrate and comprising a lower electrode comprising an aluminum-based metal and formed on the primary surface of the piezoelectric substrate, an adhesion layer formed on the lower electrode and a barrier metal layer formed on the adhesion layer and comprising a first metal layer and a second metal layer that has more impurities than the first metal layer.

2. The device of claim 1, wherein the second electrode surrounds the first electrode on the primary surface of the piezoelectric substrate.

3. The device of claim 1, wherein the second electrode is connected with the first electrode to energize the first electrode.

4. The device of claim 1, wherein the first metal layer of the barrier metal layer comprises a material comprising nickel, copper or a combination thereof.

5. The device of claim 4, wherein the second metal layer of the barrier metal layer comprises the material of the first metal layer and an impurity comprising carbon, sulfur, oxygen or a combination thereof.

6. The device of claim 1, wherein a thickness of the barrier metal layer is 0.5 to 1.5 μm.

7. The device of claim 1, wherein the adhesion layer comprises copper, titanium, vanadium, platinum or a combination thereof.

8. A method comprising:
providing a piezoelectric substrate comprising an electrode formed on a primary surface of the piezoelectric substrate to generate a surface acoustic wave,
forming a lower electrode comprising an aluminum-based metal on the primary surface of the piezoelectric substrate,
forming an adhesion layer on the lower electrode,
forming a barrier metal layer on the adhesion layer so that the barrier metal layer comprises a first metal layer and a second metal layer that has more impurities than the first metal layer, and
attaching a mounting substrate and the piezoelectric substrate using a stack of the lower electrode, the adhesion layer and the barrier layer.

9. The method of claim 8, comprising bombarding a top surface of the piezoelectric substrate, a top surface of the lower electrode, a top surface of the adhesion layer, a top surface of the barrier metal layer or a combination thereof using argon ions, oxygen ions or nitrogen ions.

10. The method of claim 8, wherein the stack is disposed on the primary surface of the piezoelectric substrate to surround the electrode to generate a surface acoustic wave.

11. The method of claim 8, wherein the stack is connected with the electrode to generate a surface acoustic wave.

12. The method of claim 8, wherein the first metal layer of the barrier metal layer comprises a material comprising nickel, copper or a combination thereof.

13. The method of claim 12, wherein the second metal layer of the barrier metal layer comprises the material of the first metal layer and an impurity that is carbon, sulfur, oxygen or a combination thereof.

14. The method of claim 8, wherein the barrier metal layer is formed to have a thickness of 0.5 to 1.5 μm.

15. The method of claim 8, wherein the adhesion layer comprises copper, titanium, vanadium, platinum or a combination thereof.

16. A band pass filter comprising:
an input terminal receiving a transmission signal,
a surface acoustic wave device receiving the transmission signal from the input terminal and removing noises from the transmission signal, and
an output terminal receiving the transmission signal from the surface acoustic wave device and supplying the transmission signal to an antenna,
wherein the surface acoustic wave device comprises the device of claim 1.

17. A band pass filter comprising:
an input terminal receiving through a duplexer a reception signal received by an antenna, and
a surface acoustic wave device receiving the reception signal from the input terminal and removing noises from the reception signal,
wherein the surface acoustic wave device comprises the device of claim 1.

18. A communication device comprising:
a mixer mixing a content signal and a carrier signal to generate a transmission signal,
a band pass filter comprising a surface acoustic wave device and removing noises from the transmission signal,
an amplifier receiving the transmission signal from the band pass filter and amplifying the transmission signal, and
an antenna receiving the amplified transmission signal through a duplexer,
wherein the surface acoustic wave device comprises the device of claim 1.

19. A communication device comprising:
an antenna receiving a reception signal comprising a content signal and a carrier signal,
an amplifier receiving the reception signal from the antenna through a duplexer and amplifying the reception signal,
a band pass filter comprising a surface acoustic wave device and removing noises from the amplified transmission signal, and
a mixer receiving the reception signal from the band pass filter and separating the content signal from the carrier signal,
wherein the surface acoustic wave device comprises the device of claim 1.

20. A method comprising:
providing a first substrate comprising a device element formed thereon,
forming on the first substrate a first metal layer comprising nickel, copper or a combination thereof as a majority constituent and having a first impurity concentration,
forming on the first metal layer a second metal layer comprising the same majority constituent as the first metal layer and having a second impurity concentration,
placing a second substrate on the second metal layer, and
heating the first and second substrates and the first and second metal layers to seal the device element,
wherein the first and second impurity concentrations are determined so that a residual stress in the first and second metal layers after the heating is lower than 200 N/m².

21. A device comprising:
a piezoelectric substrate,
an electrode formed on a primary surface of the piezoelectric substrate to generate a surface acoustic wave,
a mounting substrate, and
means for attaching the mounting substrate and the piezoelectric substrate, providing the electrode with electric connection and reducing a residual stress between the piezoelectric substrate and the mounting substrate below 200 N/m².
